(19) United States
(12) Patent Application Publication
(10) Pub. No.: US 2022/0240375 A1
(43) Pub. Date: Jul. 28, 2022

(54) CO-AXIAL VIA STRUCTURE AND MANUFACTURING METHOD OF THE SAME

(71) Applicant: Unimicron Technology Corp., Taoyuan (TW)

(72) Inventors: Ching-Sheng CHEN, Hsinchu County (TW); Chi-Min CHANG, Taoyuan City (TW); Yi-Pin LIN, Taoyuan City (TW); Jun-Rui HUANG, Tainan City (TW)

(21) Appl. No.: 17/452,771

(22) Filed: Oct. 28, 2021

Related U.S. Application Data
(60) Provisional application No. 63/142,994, filed on Jan. 28, 2021.

(30) Foreign Application Priority Data
Oct. 8, 2021 (TW) 110137649

(51) Int. Cl. H05K 1/02; H05K 3/42; H05K 3/02; H05K 3/00

(52) U.S. Cl. CPC H05K 1/0251; H05K 1/0222; H05K 1/024; H05K 3/429; H05K 2203/0723; H05K 3/0026; H05K 3/0094; H05K 3/428; H05K 3/027

(57) ABSTRACT

A co-axial structure includes a substrate, a first conductive structure, a second conductive structure, and an insulating layer. The substrate includes a first surface. The first conductive structure includes a first circuit deposited on the first surface and a first via penetrating the substrate. The second conductive structure includes a second circuit deposited on the first surface and a second via penetrating the substrate. The first via and the second via extend along a first direction. The first circuit and the second circuit extend along a second direction, and the second direction is perpendicular to the first direction. The insulating layer is located between the first via and the second via. The first conductive structure and the second conductive structure are electrically insulated. The first circuit and the second circuit are coplanar.

### CROSS-REFERENCE TO RELATED APPLICATION

This application claims priority to U.S. Provisional Application Ser. No. 63/142,994, filed Jan. 28, 2021 and Taiwan Application Series 110137649, filed Oct. 8, 2021, which are herein incorporated by reference in their entireties.

### BACKGROUND

### Field of Invention

The present invention relates to a co-axial via structure and a manufacturing method of the co-axial via.

### Description of Related Art

It is required to add extra dielectric layers between a grounding line and a signal line by a compression process for manufacture a conventional co-axial via structure which may cause greater budget consumption. In addition, inner circuits and outer lines within a via structure are located at different levels, and therefore impedance mismatch problem may occur. The dielectric layer deposited between the grounding line and the signal line may also have shielding notch which may cause poor magnetic shielding efficiency.

Accordingly, it is still a development direction for the industry to provide a co-axial via structure which can improve impedance match efficiency and magnetic shielding efficiency.

### SUMMARY

One aspect of the present disclosure is a co-axial structure.

In some embodiments, the co-axial structure includes a substrate, a first conductive structure, a second conductive structure, and an insulating layer. The substrate includes a first surface. The first conductive structure includes a first circuit deposited on the first surface and a first via penetrating the substrate. The second conductive structure includes a second circuit deposited on the first surface and a second via penetrating the substrate. The first via and the second via extend along a first direction. The first circuit and the second circuit extend along a second direction, and the second direction is perpendicular to the first direction. The insulating layer is located between the first via and the second via. The first conductive structure and the second conductive structure are electrically insulated. The first circuit and the second circuit are coplanar.

In some embodiments, the first via of the first conductive structure surrounds the second via of the second conductive structure and the insulating layer.

In some embodiments, the insulating layer, the first via, and the second via are co-axial.

In some embodiments, the insulating layer includes a protruding portion located at an end of the insulating layer close to the first surface.

In some embodiments, the protruding portion of the insulating layer protrudes away from the second through hole along the second direction.

In some embodiments, the first via of the first conductive structure, the protruding portion of the insulating layer, and the second circuit of the second conductive structure overlap along the first direction.

In some embodiments, the substrate further includes a second surface opposite to the first surface, the co-axial structure further includes a dielectric layer located between the first surface and the second surface, and the protruding portion of the insulating layer is in contact with the dielectric layer.

Another aspect of the present disclosure is a manufacturing method of a co-axial structure.

In some embodiments, the manufacturing method of a co-axial structure includes forming a first through hole in a substrate; forming a first conductive material on a first surface of the substrate and in the first through hole; forming a trench recessed from the first surface such that the trench communicates with the first through hole; forming an insulating layer in the first through hole and the trench; forming a second conductive material on the first surface of the substrate and in the first through hole; and pattering the first conductive material and the second conductive material so as to form a first circuit and a second circuit on the first surface such that the first conductive material remained and the second conductive material remained are electrically insulated through the insulating layer in the trench, and the first circuit and the second circuit are coplanar.

In some embodiments, the co-axial structure further includes a second surface opposite to the first surface, and forming the trench further includes drilling from the first surface along the first direction.

In some embodiments, the co-axial structure further includes a dielectric layer located between the first surface and the second surface, and forming the trench further includes exposing the dielectric layer from the first conductive material.

In some embodiments, forming the insulating layer in the first through hole and the trench further includes forming an insulating layer material in the first through hole and the trench such that the insulating layer material is in contact with the dielectric layer; and forming a second through hole in the insulating layer material so as to form the insulating layer, wherein the insulating layer includes a protruding portion located in the trench.

In some embodiments, forming the second conductive material on the first surface of the substrate and in the first through hole such that the insulating layer, the first conductive material in the first via, and the second conductive material in the second via are co-axial.

In some embodiments, forming the second conductive material on the first surface of the substrate and in the first through hole further includes forming the second conductive material in the second through hole such that the first conductive material in the first through hole surrounds the insulating material and the second conductive material in the second through hole.

In some embodiments, patterning the first conductive material and the second conductive material so as to form the first circuit and the second circuit such that the first conductive material in the first via, the protruding portion of the insulating layer, and the second circuit overlap along the first direction.

In the aforementioned embodiments, since the first circuit and the second circuit of the co-axial via structure are coplanar and the first conductive structure and the second conductive structure are electrically insulated through the insulating layer, the co-axial via structure of the present disclosure can have better magnetic noise shielding efficiency and impedance match efficiency that can improve high frequency signal integrality. In addition, the number of the dielectric layers can be reduced so as to reduce the thickness of the co-axial structure. Therefore, manufacture cost of the co-axial via structure of the present disclosure can be reduced.

### BRIEF DESCRIPTION OF THE DRAWINGS

The invention can be more fully understood by reading the following detailed description of the embodiment, with reference made to the accompanying drawings as follows:

FIG. 1 is a three-dimensional view of the co-axial via structure according to one embodiment of the present disclosure;

FIG. 2 is a cross-sectional view taken along line 2-2 in FIG. 1;

FIGS. 3A to 11A are top views of intermediate steps of a manufacturing method of a co-axial via structure according to another embodiment of the present disclosure; and

FIGS. 3B to 11B are cross-sectional views taken along line 3B-3B to line 11B-11B in FIGS. 3A to 11A, respectively.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

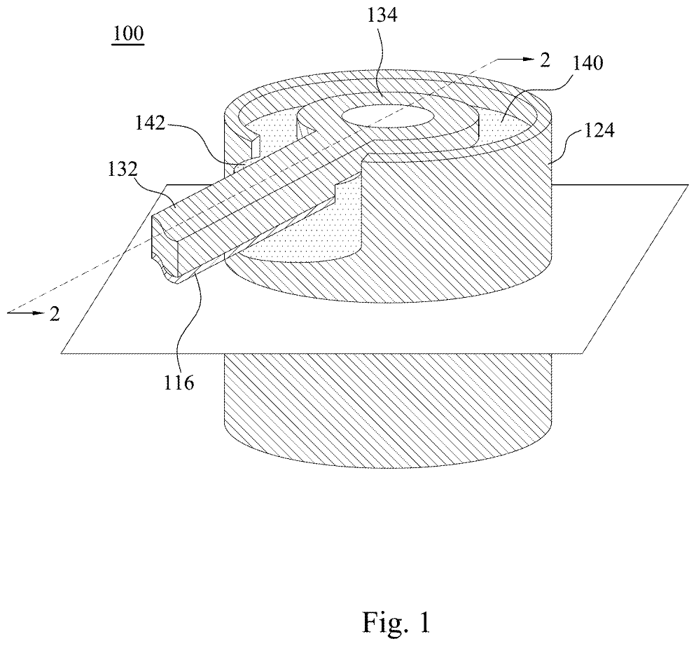

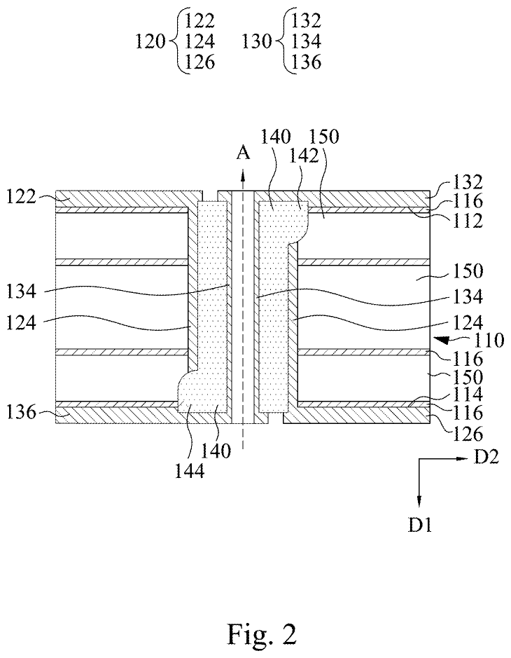

FIG. 1 is a three-dimensional view of the co-axial via structure 100 according to one embodiment of the present disclosure. FIG. 2 is a cross-sectional view taken along line 2-2 in FIG. 1. Reference is made to FIG. 1 and FIG. 2 simultaneously. The co-axial via structure 100 includes a substrate 110, a first conductive structure 120, a second conductive structure 130, and an insulating layer 140.

The substrate 110 includes a first surface 112 and a second surface 114 opposite to each other. The first conductive structure 120 includes a first circuit 122 and a first via 124, and the second conductive structure 130 includes a second circuit 132 and a second via 134. The first circuit 122 and the second circuit 132 are deposited on the first surface 112. The first via 124 and the second via 134 penetrate the substrate 110. The first via 124 and the second via 134 extend along a first direction D1. The first circuit 122 and the second circuit 132 extend along a second direction D2 perpendicular to the first direction D1. The first circuit 122 of the first conductive structure 120 and the second circuit 132 of second conductive structure 130 are coplanar. In other words, the first circuit 122 and the second circuit 132 are located at the same horizontal plane.

In the present embodiment, the first direction D1 is the vertical direction herein. That is, the first direction D1 is a direction from the first surface 112 to the second surface 114. The second direction D2 can be arbitrary horizontal direction that is perpendicular to the first direction D1. In the present embodiment, the first circuit 122 and the third circuit 126 can be ground lines, and the second circuit 132 and the fourth circuit 136 can be signal lines, but the present disclosure is not limited in those regards.

As shown in FIG. 2, the first conductive structure 120 further includes a third circuit 126 located on the second surface 114, and the second conductive structure 130 further includes a fourth circuit 136 located on the second surface 114. Two ends of the first via 124 are connected with the first circuit 122 and the third circuit 126 respectively. Two ends of the second via 134 are connected with the second circuit 132 and the fourth circuit 136 respectively. The third circuit 126 and the fourth circuit 136 extend along the second direction D2, and the third circuit 126 and the fourth circuit 136 are coplanar. In other words, the third circuit 126 and the fourth circuit 136 are located at the same horizontal plane.

The insulating layer 140 is located between the first via 124 and the second via 134, and the insulating layer 140 extend along the first direction D1. The first via 124 surrounds the second via 134 and the insulating layer 140, and the insulating layer 140 surrounds the second via 134. As shown in FIG. 2, the insulating layer 140, the first via 124, and the second via 134 are co-axial relative to an axis A.

The insulating layer 140 includes a first protruding portion 142, and the first protruding portion 142 is located at one end of the insulating layer 140 close to the first surface 112. The first protruding portion 142 protrudes away from the second via 134 along the second direction D2. As shown in FIG. 2, the substrate 110 further includes dielectric layers 150 located between the first surface 112 and the second surface 114. In the present embodiment, the substrate 110 further includes multiple inner circuits 116 separated through the dielectric layers 150, but the present disclosure is not limited in this regard. The first protruding portion 142 of the insulating layer 140 is in contact with the dielectric layers 150 close to the first surface 112. In other words, the first protruding portion 142 penetrates through the first via 124 and extends to the dielectric layers 150.

It is noted that, in order to describe the structural relation between the second circuit 132 and the first protruding portion 142, only the first via 124, the second circuit 132, and the insulating layer 140 are illustrated in FIG. 1, and the first circuit 122 is omitted.

As shown in FIG. 2, the first via 124 of the first conductive structure 120, the first protruding portion 142 of the insulating layer 140, and the second circuit 132 of the second conductive structure 130 overlap along the first direction D1. The second circuit 132 of the second conductive structure 130 extends from the second via 134 and cross the first protruding portion 142. In other words, the first via 124 and the second circuit 132 are electrically insulated through the first protruding portion 142, and the first circuit 122 and the second circuit 132 which are co-axial are separated from each other. As such, the first conductive structure 120 and the second conductive structure 130 are electrically insulated.

Accordingly, since the first circuit 122 and the second circuit 132 of the co-axial via structure 100 are coplanar and the first conductive structure 120 and the second conductive structure 130 are electrically insulated, the step of forming extra dielectric layers to electrically insulate a first circuit and a second circuit located at different layers can be omitted. As such, the first via 124 and the second via 134 can have substantially the same height, and therefore the overall structure of the co-axial via structure 100 is more symmetrical so as to improve impedance match efficiency. In addition, since the dielectric layers located at different layers can be omitted, the second via 134 can be prevented from penetrating throughout the insulating layer. As such, the co-axial via structure 100 can avoid poor magnetic shielding due to notch of the shielding structure.

As shown in FIG. 2, the insulating layer 140 further includes a second protruding portion 144, and the second protruding portion 144 is located at one end of the insulating layer 140 close to the second surface 114. The second protruding portion 144 protrudes away from the second via 134 along the second direction D2. The second protruding portion 144 of the insulating layer 140 is in contact with the dielectric layers 150 close to the second surface 114. In other words, the second protruding portion 144 penetrates through the first via 124 and extends to the dielectric layers 150.

As shown in FIG. 2, the first via 124 of the first conductive structure 120, the second protruding portion 144 of the insulating layer 140, and the fourth circuit 136 of the second conductive structure 130 overlap along the first direction D1. The fourth circuit 136 of the second conductive structure 130 extends from the second via 134 and cross the second protruding portion 144. In other words, the first via 124 and the fourth circuit 136 are electrically insulated through the second protruding portion 144, and the third circuit 126 and the fourth circuit 136 are separated from each other. As such, the first conductive structure 120 and the second conductive structure 130 are electrically insulated.

As described above, the extension direction of the fourth circuit 136 can be arbitrary horizontal direction that is perpendicular to the first direction D1. FIG. 2 is merely an example, and the present disclosure is not limited in this regard.

It is to be noted that the connection relationships, materials, and advantages of the elements described above will not be repeated. In the following description, a manufacturing method of the co-axial structure will be described.

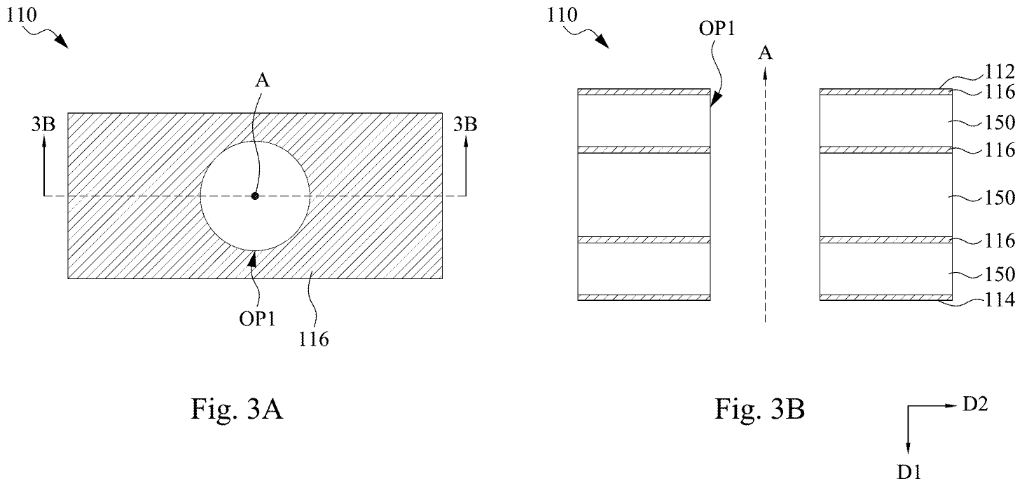

FIGS. 3A to 11A are top views of intermediate steps of a manufacturing method of a co-axial via structure according to another embodiment of the present disclosure. FIGS. 3B to 11B are cross-sectional views taken along line 3B-3B to line 11B-11B in FIGS. 3A to 11A, respectively. As shown in FIG. 3A and FIG. 3B, the manufacturing method of the co-axial structure starts from formed the first through hole OP1 in a substrate 110. The first through hole OP1 penetrates through the inner circuits 116 and the dielectric layers 150 of the substrate 110. For example, the method of forming the first through hole OP1 can be laser drilling.

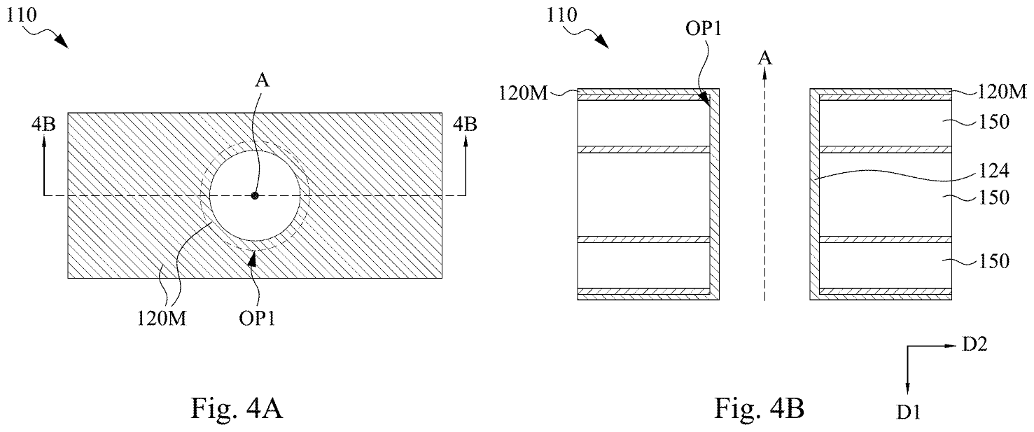

As shown in FIG. 4A and FIG. 4B, in the manufacturing method of the co-axial via structure, a first conductive material 120M is subsequently formed on the first surface 112, on the second surface 114, and on an inner wall of the first through hole OP1. For example, the method of forming the first conductive material 120M can be electroplating, and the first conductive material 120M includes copper, but the present disclosure is not limited in these regards. A person having ordinary skill in the art can choose suitable method and materials based on practical condition.

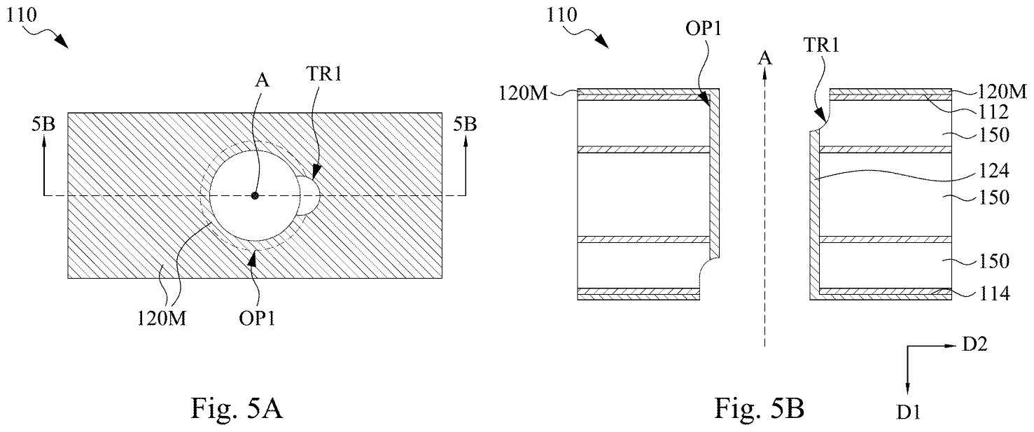

As shown in FIG. 5A and FIG. 5B, in the manufacturing method of the co-axial via structure, a first trench TR1 is subsequently formed. The first trench TR1 is recessed from the first surface 112, and the first trench TR1 and the first through hole OP1 communicate with each other. The method of forming the first trench TR1 includes drilling from the first surface 112 through the first direction D1 such that the dielectric layer 150 close to the first surface 112 can be exposed from the first conductive material 120M.

Reference is made to FIG. 5B, this step further includes forming a second trench TR2. The second trench TR2 is recessed from the second surface 114, and the second trench TR2 and the first through hole OP1 communicate with each other. The method of forming the second trench TR2 includes drilling from the second surface 114 through a reversed direction of the first direction D1 such that the dielectric layer 150 close to the second surface 114 can be exposed from the first conductive material 120M. The method of forming the first trench TR1 and the second trench TR2 can be laser drilling.

In a top view of FIG. 5A, a distance between the first trench TR1 and the first through hole OP1 can be derived from the width of the second circuit 132 and an required interval between the first circuit 122 and the second circuit 132. Similarly, in a bottom view (not shown), a distance between the second trench TR2 and the first through hole OP1 can be derived from the width of the fourth circuit 136 and an required interval between the third circuit 126 and the fourth circuit 136.

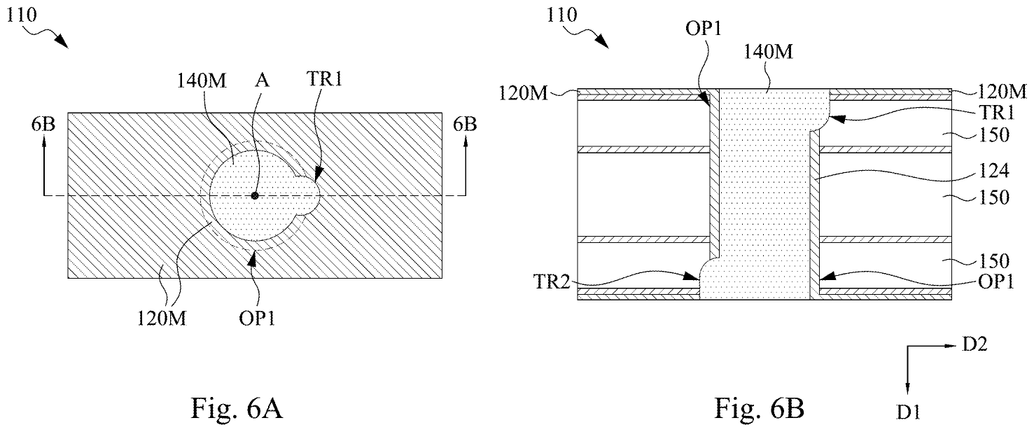

As shown in FIG. 6A and FIG. 6B, in the manufacturing method of the co-axial via structure, an insulating layer material 140M is filled in the first through hole OP1, the first trench TR1, and the second trench TR2 such that the insulating layer material 140M is in contact with the dielectric layer 150 exposed form the first conductive material 120M. In the present embodiment, the insulating layer material 140M, for example, can include filling paste, but the present disclosure is not limited in this regard. After filling the insulating layer material 140M, the portion of the insulating layer material 140M protruding from the first surface 112 and the second surface 114 are polished such that a top surface and a bottom surface of the insulating layer 140M are level with the first conductive material 120M, respectively.

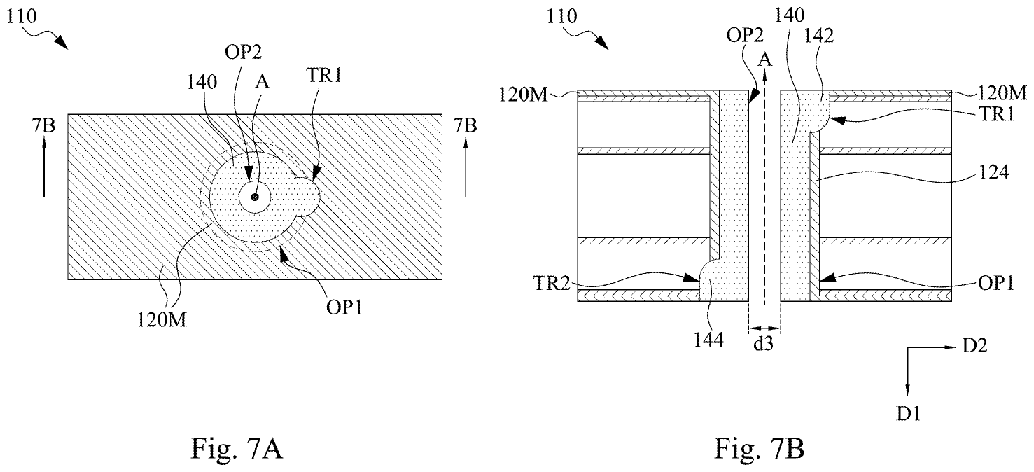

As shown in FIG. 7A and FIG. 7B, in the manufacturing method of the co-axial via structure, a second through hole OP2 is subsequently formed in the insulating layer material 140M. In the present embodiment, the second through hole OP2 and the first through hole OP1 are concentric. For example, the method of forming the second through hole OP2 can be laser drilling so as to remove a portion of the insulating layer material 140M. After forming the second through hole OP2, the remained insulating layer material 140M includes a portion that is located in the first through hole OP1 (i.e., the insulating layer 140) and a first protruding portion 142 and a second protruding portion 144 that are respectively located at two opposites of the substrate 110.

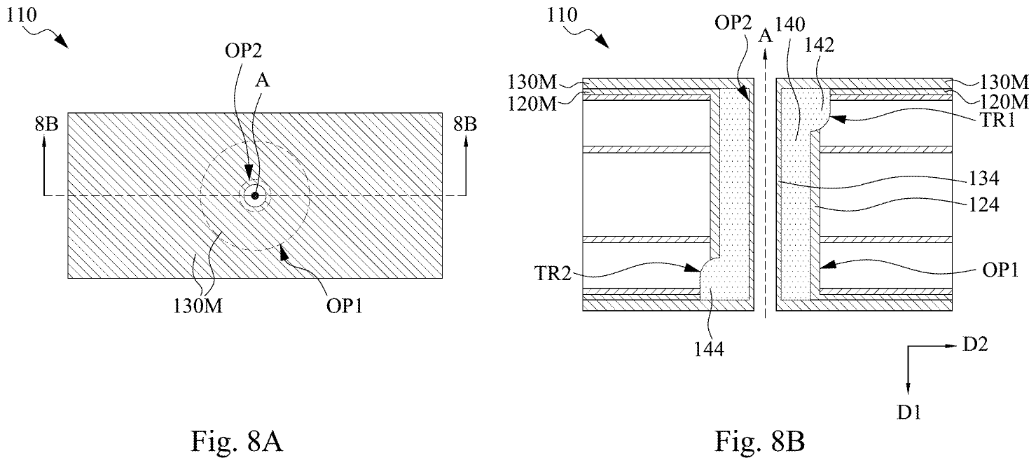

As shown in FIG. 8A and FIG. 8B, in the manufacturing method of the co-axial via structure, a second conductive material 130M is subsequently formed on the first surface 112, on the second surface 114, and on an inner wall of the second through hole OP2. For example, the method of forming the second conductive material 130M can be electroplating, and the second conductive material 130M includes copper, but the present disclosure is not limited in these regards. A person having ordinary skill in the art can choose suitable method and materials based on practical condition.

The second conductive material 130M is in the second through hole OP2, and the first conductive material 120M in the first through hole OP1 (i.e., the first via 124) surrounds the insulating layer 140 and the second conductive material 130M in the second through hole OP2 (i.e., the second via 134) such that the insulating layer 140, the first conductive material 120M in the first through hole OP1, and the and the second conductive material 130M in the second through hole OP2 are co-axial relative to the axis A.

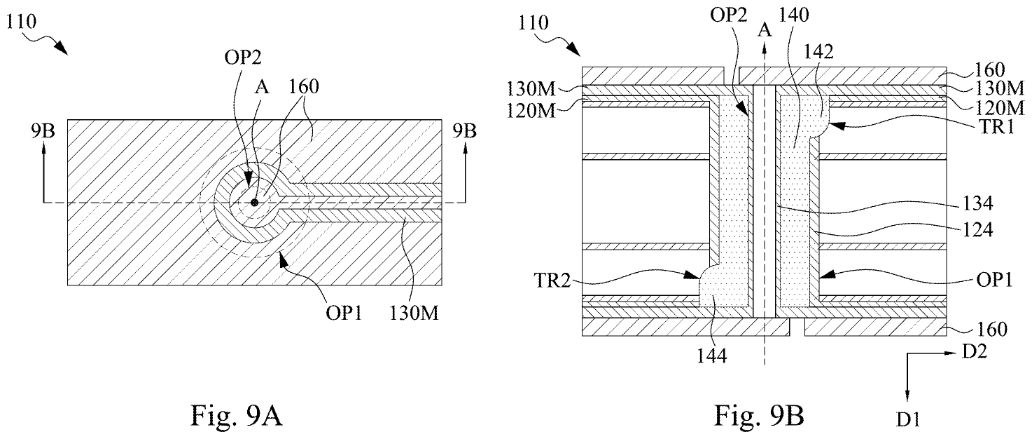

As shown in FIG. 9A and FIG. 9B, in the manufacturing method of the co-axial via structure, a photomask 160 is subsequently formed on the first surface 112 and the second surface 114. The photomask 160 includes patterns used to from the first circuit 122 and the second circuit 132 and patterns used to from the third circuit 126 and the fourth circuit 136.

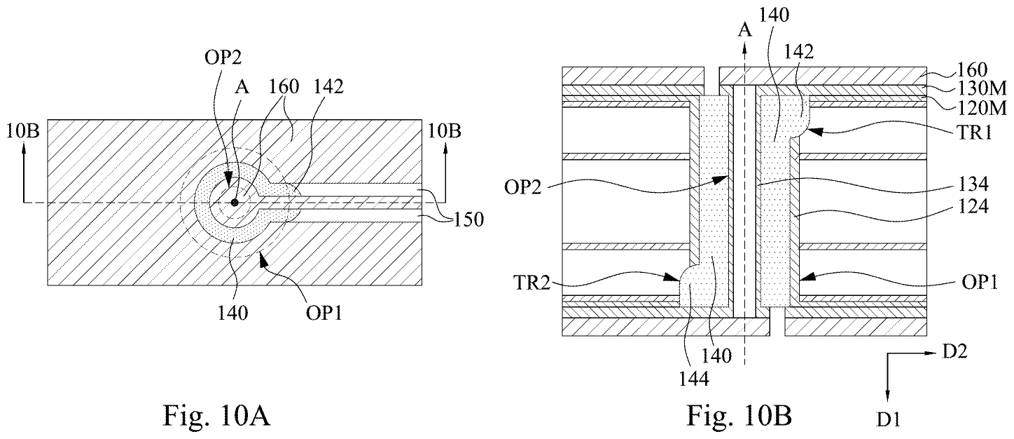

As shown in FIG. 10A and FIG. 10B, in the manufacturing method of the co-axial via structure, the first conductive material 120M and the second conductive material 130M are subsequently patterned by using the photomask 160. Subsequently, the first conductive material 120M and the second conductive material 130M exposed from the photomask 160 are continuously removed until the insulating layer 140 and the dielectric layer 150 are exposed from the photomask 160.

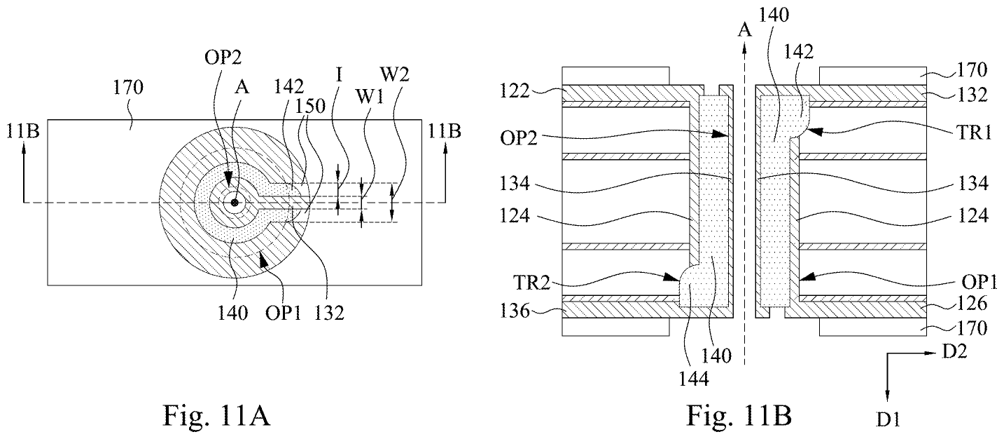

Reference is made to FIG. 10A, FIG. 10B, FIG. 11A, and FIG. 11B. In the manufacturing method of the co-axial via structure, the photomask 160 is removed later so as to form a insulating protection layer 170. The insulating protection layer 170 includes an opening for connecting with the conductive elements such as metal bump, bump, or solder ball (not shown).

As shown in FIG. 11B, after those steps mentioned above, the first circuit 122 and the second circuit 132 separated from each other are formed, and the first circuit 122 and the second circuit 132 are coplanar. The first via 124 and the second circuit 132 are electrically insulated through the first protruding portion 142 of the first trench TR1. The first circuit 122 can include arbitrary circuit pattern as long as the first circuit 122 and the second circuit 132 can be electrically insulated.

Similarly, after those steps mentioned above, the third circuit 126 and the fourth circuit 136 separated from each other are formed, and the third circuit 126 and the fourth circuit 136 are coplanar. The first via 124 and the fourth circuit 136 are electrically insulated through the second protruding portion 144 of the second trench TR2. The third circuit 126 can include arbitrary circuit pattern (not shown) as long as the third circuit 126 and the fourth circuit 136 can be electrically insulated.

Reference is made to FIG. 11A. In the present embodiment, the second circuit 132 has a width W1, and a junction between the insulating layer 140 and the first protruding portion 142 has a width W2. The width W2 can be adjusted by changing the distance between the first trench TR1 and the first through hole OP1, and the W2 can be determined on the hole diameter of the first trench TR1. Therefore, based on the required width W1, a suitable distance between the first trench TR1 and the first through hole OP1 can be calculated in the step of forming the first trench TR1. As such, the width W2 is guaranteed to be width enough to avoid broken of the second circuit 132. The second circuit 132 and the adjacent first circuit 122 have an interval I therebetween. Under constraints for deriving specific impedance, the interval I can be determined according to a thickness and the width W1 of the second circuit 132, and parameters of the dielectric layer 150 so as to improve impedance match efficiency.

In summary, since the ground line and the signal line (first circuit and the second circuit) of the co-axial via structure are coplanar and the first conductive structure and the second conductive structure are electrically insulated through the insulating layer, the co-axial via structure of the present disclosure can have better magnetic noise shielding efficiency and impedance match efficiency that can improve high frequency signal integrality. In addition, the number of the dielectric layers can be reduced so as to reduce the thickness of the co-axial structure. Therefore, manufacture cost of the co-axial via structure of the present disclosure can be reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A co-axial structure, comprising:
a substrate comprising a first surface;
a first conductive structure comprising a first circuit deposited on the first surface and a first via penetrating the substrate;
a second conductive structure comprising a second circuit deposited on the first surface and a second via penetrating the substrate, wherein the first via and the second via extend along a first direction, and the second direction is perpendicular to the first direction; and
an insulating layer located between the first via and the second via, wherein the first conductive structure and the second conductive structure are electrically insulated, and the first circuit and the second circuit are coplanar.

2. The co-axial structure of claim 1, wherein the first via of the first conductive structure surrounds the second via of the second conductive structure and the insulating layer.

3. The co-axial structure of claim 1, wherein the insulating layer, the first via, and the second via are co-axial.

4. The co-axial structure of claim 1, wherein the insulating layer comprises a protruding portion located at an end of the insulating layer close to the first surface.

5. The co-axial structure of claim 4, wherein the protruding portion of the insulating layer protrudes away from the second through hole along the second direction.

6. The co-axial structure of claim 4, wherein the first via of the first conductive structure, the protruding portion of the insulating layer, and the second circuit of the second conductive structure overlap along the first direction.

7. The co-axial structure of claim 4, wherein the substrate further comprises a second surface opposite to the first surface, the co-axial structure further includes a dielectric layer located between the first surface and the second surface, and the protruding portion of the insulating layer is in contact with the dielectric layer.

8. A manufacturing method of a co-axial structure, comprising:
forming a first through hole in a substrate;
forming a first conductive material on a first surface of the substrate and in the first through hole;
forming a trench recessed from the first surface such that the trench communicates with the first through hole;
forming an insulating layer in the first through hole and the trench;
forming a second conductive material on the first surface of the substrate and in the first through hole; and
pattering the first conductive material and the second conductive material to form a first circuit and a second circuit on the first surface such that a remained first conductive material and a remained second conductive material are electrically insulated through the insulating layer in the trench, and the first circuit and the second circuit are coplanar.

9. The manufacturing method of claim 8, wherein the co-axial structure further comprises a second surface opposite to the first surface, and forming the trench further comprises:
drilling from the first surface along a first direction.

10. The manufacturing method of claim 8, wherein the co-axial structure further comprises a dielectric layer located between the first surface and the second surface, and forming the trench further comprises:
exposing the dielectric layer from the first conductive material.

11. The manufacturing method of claim 10, wherein forming the insulating layer in the first through hole and the trench further comprises:
forming an insulating layer material in the first through hole and the trench such that the insulating layer material is in contact with the dielectric layer; and
forming a second through hole in the insulating layer material so as to form the insulating layer, wherein the insulating layer comprises a protruding portion located in the trench.

12. The manufacturing method of claim 11, wherein forming the second conductive material on the first surface of the substrate and in the first through hole further comprises:
forming the second conductive material in the second through hole such that the first conductive material in the first through hole surrounds the insulating layer and the second conductive material in the second through hole.

13. The manufacturing method of claim 12, wherein forming the second conductive material on the first surface of the substrate and in the first through hole such that the insulating layer, the first conductive material in the first via, and the second conductive material in the second via are co-axial.

14. The manufacturing method of claim 8, wherein patterning the first conductive material and the second conductive material so as to form the first circuit and the second circuit such that the first conductive material in the first via, the protruding portion of the insulating layer, and the second circuit overlap along the first direction.
